(19) United States
(12) Patent Application Publication
(10) Pub. No.: US 2026/0289066 A1
(43) Pub. Date: Sep. 24, 2026

(54) DATA BLENDING OF MANAGEMENT DATA AND SYNTHETIC TRAFFIC DATA FOR VERIFICATION OF DESIGNS-UNDER-TEST (DUTs)

(71) Applicant: Siemens Industry Software Inc., Plano, TX (US)

(72) Inventors: John Ramses, Cairo (EG); Georges Antoun, Neu-Kairo (EG); Mazin Roushdy, Cairo (EG); Sakari Ollitervo, Martinniemi (FI); Ronald James Squiers, Castro Valley, CA (US)

(73) Assignee: Siemens Industry Software Inc., Plano, TX (US)

(21) Appl. No.: 19/475,668

(22) PCT Filed: Apr. 28, 2023
(86) PCT No.: PCT/US2023/066342

§ 371 Date: Oct. 15, 2025

(51) Int. Cl. G06F 30/398

(52) U.S. Cl. CPC G06F 30/398

(57) ABSTRACT

A system may include a verification platform configured to represent a design-under-test (DUT) to verify operation of the DUT. The system may also include a computing system comprising a data construction engine configured to construct management data to configure the DUT in a given manner and a data blending engine. The data blending engine may be configured to access synthetic traffic data to test the operation of the DUT, blend the management data and the synthetic traffic data into a blended data stream, and communicate the blended data stream comprising the management data and the synthetic data across a physical communication link to the verification platform that represents the DUT.

### BACKGROUND

Electronic circuits, such as integrated circuits, are used in nearly every facet of modern society, from automobiles to microwaves to personal computers and more. Design of circuits may involve many steps, known as a “design flow.” The particular steps of a design flow are often dependent upon the type of circuit being designed, its complexity, the design team, and the circuit fabricator or foundry that will manufacture the circuit. Electronic design automation (EDA) applications support the design and verification of circuits prior to fabrication. EDA applications may implement various procedures, e.g., functions, tools, or features to analyze, test, or verify a circuit design at various stages of the design flow.

### BRIEF DESCRIPTION OF THE DRAWINGS

Certain examples are described in the following detailed description and in reference to the drawings.

FIG. 1 shows an example of a system that supports data blending of management data and synthetic traffic data for verification of designs-under-test (DUTs).

FIG. 2 shows an example generation of a blended data stream that includes management data to configure operation of a DUT and traffic data to test operation of the DUT.

FIG. 3 shows an example blending of management data into a packet stream that includes synthetic traffic data.

FIG. 4 shows an example of logic that a system may implement to support data blending of management data and synthetic traffic data for verification of DUTs.

FIG. 5 shows an example of a computing system that supports data blending of management data and synthetic traffic data for verification of DUTs.

### DETAILED DESCRIPTION

With advances in modern technology, various verification technologies have been developed to validate the operation of devices of nearly any type and complexity. Verification platforms are especially prevalent in the validation, testing, and analysis of integrated circuits (ICs). System-on-chip (SoC) designs are becoming increasingly complex, and verification platforms may implement a suite of emulation and simulation capabilities to test SoCs as designs-under-test (DUTs). Hardware emulators, software-based simulation systems, field programmable gate array (FPGA) prototyping, and various other technologies may be utilized to support design verification of increasingly complex IC devices. A verification platform may represent or otherwise contain a DUT for testing and validation through any such technologies. For example, a verification platform may represent (e.g., implement a representation) the DUT through a behavior model, through FPGA or other hardware-based emulations, through software simulations, etc.

Modern verification systems are used for verification beyond conventional SoCs and chip designs. As one example, verification platforms can support the testing and validation of DUTs in the form of communication networks (and underlying network), such as cellular network devices, including radios, fronthaul networks and components thereof, distributed units, antennas, routing structures, and any other type of network device. Network speeds, bandwidth, volume, and communication capabilities continue to rapidly advance, and verification of communication networks and network devices, including network application specific ICs (ASICs), can require increasingly capable verification platforms.

One challenge in verification of DUTs as network devices (such as 5G fronthaul network devices) is that configuration of a DUT represented by a verification platform can be a cumbersome and complex task. For fronthaul network and other network device DUTs verified via emulation or simulation of verification platforms, options for DUT configuration (e.g., configuration of 5G radio unit or other network device DUTs) are limited. In some instances, a user (e.g., a testing engineer) can directly configure the DUT via physical access to the verification platform. However, manual DUT configurations may require direct access to the verification platform itself to make even a simple DUT parameter change, which can be cumbersome, error-prone, and inefficient.

As an option for DUT configurations in verification of network devices in particular, one possibility is to leverage a management plane (M-plane) for network devices implemented according to Open Radio Access Network (O-RAN) specifications. However, traditional verification platforms provide limited options for communicating across the management plane to configure DUT operation. Users may themselves develop private or proprietary testbenches for use in DUT verifications, and such testbenches may include specifically generated M-Plane data to configure DUTs for specific uses. However, such testbenches are often disparate from another, implemented by differing third-party solutions utilizing software protocols and products distinct from the verification platform.

Moreover, management data of M-planes can be stateful in nature in that management data can alter or configure an internal state of a network device (or downstream device). Generation of such stateful data to configure DUTs can vary greatly based on the specific DUT being verified and the particular verification being performed for the DUT. This drawback may be particularly limiting when protocol or other stateful verifications are required on a real-time basis. In some conventional solutions, like virtual Ethernet, packet generation for stateful protocols can be performed using synthetic generators, e.g., scripted packet sequences configured to generate TCP/IP packets with customizable fields to provide to a DUT for configuration purposes. While scripted command sequences can generate management data through customized fields of transferred packets, such techniques are unable to support verifications of DUT communication exchanges in real-time stateful scenarios. Virtual verification implementations would be similarly limited, as scripted packet sequences are unable to verity the order and totality of all stateful responses from a DUT.

As another drawback of conventional verification systems, M-plane communications can be limited to a dedicated communication port in verification systems, such as a dedicated Ethernet port of a verification platform through which M-plane traffic is communicated to directly alter DUT configurations and parameter registers. Such designs limit the efficiency of verification platforms by requiring dedicated communication channels, and this limitation can become increasingly exacerbated when network device validations require immense amounts of communication bandwidth to properly test device performance and behavior. Such ports may also require additional hardware, such as speed bridges to coordinate timing of M-plane data. Additionally, many conventional methods to communication M-plane data to configure DUTs cannot be performed dynamically, e.g., during a verification process of the network device or contemporaneously with the transmission of network traffic data to test performance of network devices across the same communication channel. Beyond M-plane data for configuration of O-RAN network devices, similar limitations can exist for DUT configurations of other types of devices and DUTs as well.

The disclosure herein may provide systems, methods, devices, and logic for data blending of management data and synthetic traffic data for verification of DUTs. The data blending technology of the present disclosure may support the blending of multiple sources of data for communication across a common communication channel. As a particular example, the data blending technology described herein may blend management data to configure a DUT with the traffic data used to test the DUT. By utilizing a communication channel by which traffic data is communicated to a verification platform and DUT, blending of management data into such a data stream can allow for dynamic updates to the configuration, operation, or state of a DUT (e.g., of one or more devices represented by the DUT). Reactive dependencies between the data traffic, management data, and DUT functionality can be implemented to more fully test DUT systems, and better mimic real-life scenarios and operations of devices and systems represented through the DUT.

These and other data blending features and technical benefits according to the present disclosure are described in greater detail herein.

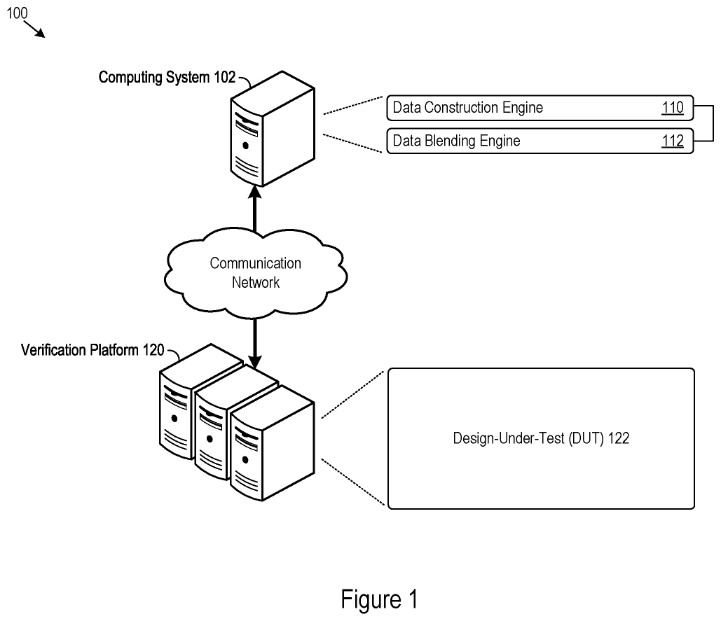

FIG. 1 shows an example of a system 100 that supports data blending of management data and synthetic traffic data for verification of designs-under-test. The system 100 may provide verification capabilities for designs-under-test (DUTs), for example through emulation or simulation-based verifications. In the example shown in FIG. 1, the system 100 includes a computing system 102 as well as a verification platform 120. The verification platform 120 may comprise a combination of hardware and software that supports simulation or emulation of physical devices represented by the verification platform 120 in the form of DUTs.

For instance, the verification platform 120 may take the form of a hardware-assisted verification platform, which may provide various device verification features such as virtual platforms, hardware emulation capabilities, field programmable gate array (FPGA) prototyping technologies, and such. In the example of FIG. 1, the hardware verification platform 120 represents the DUT 122, and the verification platform 120 may do so through any supported verification technology to emulate or simulate a system or network device (e.g., system on a chip, network device, communication network, and the like) that the DUT 122 may take the form of. Accordingly, the DUT 122 may take the form of a particular network device or network system and the verification platform 120 may thus provide any combination of suitable verification technologies for verification of a system, network, or device as the DUT 122.

In the example of FIG. 1, the system 100 also includes a computing system 102. The computing system 102 may be linked to the verification platform 120 through any suitable communication network (e.g., a direct network link or through intermediate network devices and networks). In some implementations, the computing system 102 may take the form of a user terminal by which testing, configuration, verification, management, or any other operation can be controlled or initiated on DUTs represented by the verification platform 120. In that regard, the computing system 102 may provide any number of interface capabilities by which a user may control testing, verification, and analyses of DUTs represented by the verification platform 120. The computing system 102 may take the form of a single or multiple computing devices such as compute nodes, desktop or laptop computers, smart phones or other mobile devices, tablet devices, embedded controllers, and more. In some implementations, the computing system 102 may take the form of a workstation that supports testbench executions, DUT configurations, DUT behavior analyses, or other suitable operations in support of DUT-based verification of devices.

The data blending technology of the present disclosure may be implemented through any computing system that interfaces with the verification platform 120, such as the computing system 102 of FIG. 1. In that regard, the computing system 102 may provide any combination of the data blending features described herein to blend management data to configure DUT characteristics (including of device components of the DUT 122) with traffic data used to test operation of the DUT 122. Through the various features described herein, the data blending technology of the present disclosure may provide support dynamic adaptations of DUT configurations, states, and DUT-supported protocols, support for reactive dependencies between DUT configurations and traffic data to test the DUT 122, and increased efficiency in the communication and configuration of DUTs through a common communication channel with testing data.

As an example implementation to support any combination of the data blending features described herein, the computing system 102 shown in FIG. 1 includes a data construction engine 110 and a data blending engine 112. The computing system 102 may implement the engines 110 and 112 (including components thereof) in various ways, for example as hardware and programming. The programming for the engines 110 and 112 may take the form of processor-executable instructions stored on a non-transitory machine-readable storage medium and the hardware for the engines 110 and 112 may include a processor to execute those instructions. A processor may take the form of single processor or multi-processor systems, and in some examples, the computing system 102 implements multiple engines using the same computing system features or hardware components (e.g., a common processor or a common storage medium).

In operation, the verification platform 120 may represent the DUT 122 to verify operation of the DUT 122 (e.g., verification operation of DUTs in the form of a system or device, such as a network device). In operation, the data construction engine 110 may construct management data to configure the DUT 122 in a given manner. In operation, the data blending engine 112 may access synthetic traffic data to test the operation of the DUT 122, blend the management data and the synthetic traffic data into a blended data stream, and communicate the blended data stream comprising the management data and the synthetic data across a physical communication link to the verification platform 120 that represents the DUT 122.

These and other features of the data blending technology of the present disclosure are described in greater detail next. Many of the examples described herein are provided using DUTs in the form of communication network components, e.g., fronthaul networks or underlying network devices, such as radios, antennas, etc. At times herein, the term DUT as referenced within a verification platform is used interchangeable with network device(s) that the DUT may take the form of. Such network device DUT examples are provided for illustrative purposes, and the data blending technology described herein may be consistently implemented and applied to the configuration, management, control, and testing of any device type or system that DUTs and verification platforms are configured to verify. A few examples of management data are described for DUT configuration, but data blending technology of the present disclosure can be consistently applied to blend any type of live traffic with synthetic traffic data for communication across a common channel.

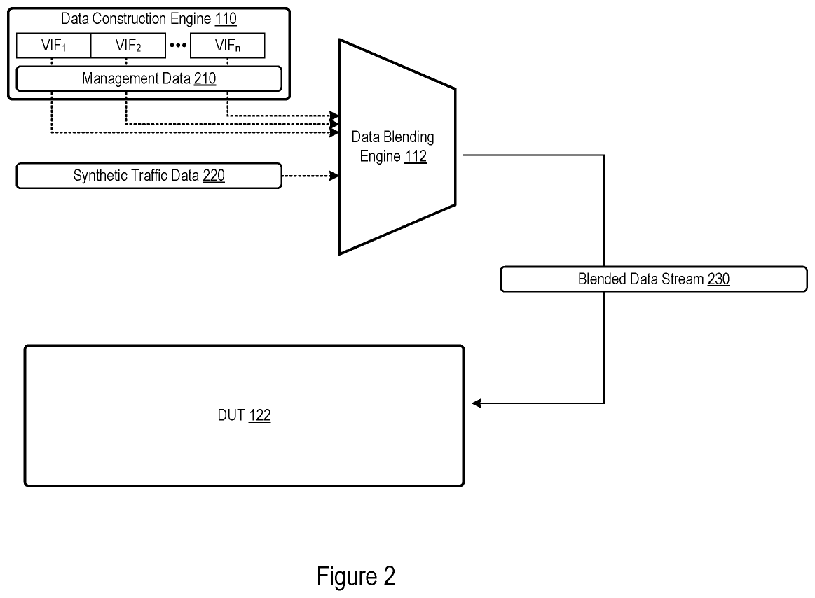

FIG. 2 shows an example generation of a blended data stream that includes management data to configure operation of a DUT and traffic data to test operation of the DUT. Various example features of FIG. 2 are described and implemented through the data construction engine 110 and the data blending engine 112, though any suitable implementation is contemplated herein. A computing system may implement the features described in FIG. 2 to support any of the data blending features described herein.

In support of data blending technologies of the present disclosure, the data construction engine 110 may construct management data to configure DUTs, such as the DUT 122 shown in FIG. 2. The management data constructed by the data construction engine 110 may comprise any data that configures a characteristic, operation, state, supported protocol, or behavior of the DUT 122. Examples of management data that the data construction engine 110 may generate to configure the DUT 122 include auto-negotiation parameters, device advertisement features (e.g., capability notification messaging, modalities, etc.), time-of-day updates, IP address allocations, configuration and advertisement of supported security suites and encryption schemes, software upgrades for DUT-represented network devices, e.g., for radios or other devices part of the DUT 122. For O-RAN compliant network systems or devices that the DUT 122 make take the form of, the data construction engine 110 may generate management plane data to configure any of the network devices (e.g., radios, antennas, or other network component) that are part of the DUT 122 or form the DUT 122 itself.

The data construction engine 110 may generate management data according to any number or combination of different protocols and services. As an illustrative example, the DUT 122 may take the form of a radio unit design to verify fronthaul port communications (e.g., Ethernet) to and from the DUT 122. The data construction engine 110 may support construction of management data that maintains M-plane links with the DUT 122 with different communication services and protocols, e.g., Internet Control Message Protocol (ICMP), Secure Shell (SSH), Dynamic Host Configuration Protocol (DHCP), and any other suitable communication service or protocol. To support multiple protocols with management data constructed for the DUT 122, the data construction engine 110 may implement, instantiate, or otherwise utilize multiple virtual network interfaces, such as those labeled as “VIF₁”, “VIF₂”, and “VIFₙ” in FIG. 2. The virtual network interfaces may stimulate the DUT 122 through the generated management data, e.g., generated protocol data units specific to the particular protocol or service provided by a given virtual network interface.

The data construction engine 110 may support generation of any type of management data according to a specific protocol, service, or configuration to control operation of the DUT 122. In some implementations, the data construction engine 110 may provide a user interface by which a user can select specific protocols, characteristics, or configurations by which to configure the DUT 122. Responsive to such selections, the data construction engine 110 may generate management data to effectuate the user selections. For example, the data construction engine 110 may construct the management data according to a user input to configure a network device (e.g., radio) for verification through the DUT 122 in a given manner, e.g., according to a particular ICMP configuration, auto-negotiation scheme, encryption capability, or any other suitable configuration for the network device.

In the example of FIG. 2, the data construction engine 110 generates the management data 210, which the data blending engine 112 may blend with other traffic data communicated to the DUT 122 to test the DUT 122. Such an example is shown in FIG. 2 through the synthetic traffic data 220, which the data blending engine 112 may access to blend with the management data 210. As used herein, the synthetic traffic data 220 may comprise any data that is designed to test operation of any device(s) or system(s) that a DUT takes the form of and which is represented by a verification platform, such as the DUT 122. For DUTs in the form of fronthaul networks or radio network devices, the synthetic traffic data 220 may include radio traffic, such as user plane traffic that may be communicated across a communication network and processed by a fronthaul network or control plane traffic that controls different radio operations (e.g., scheduling, beamforming, etc.).

Accordingly, the synthetic traffic data 220 may take the form of data of a data plane, data of a control plane, or combinations of both. The synthetic traffic data 220 may lack (e.g., not include) stateful traffic, and as such cannot alter a state of a downstream network device. In some implementations, the synthetic traffic data 220 may be locally generated, e.g., local to a computing system 102 via a script or other data generation technique. Thus, the synthetic traffic data 220 need not be generated by live users of a communication network and may instead take the form of script-generated traffic data from iterative executions of a locally-running script or from a synthetic traffic generator (e.g. traffic generation logic) implemented by the computing system 102.

The data blending engine 112 may blend management data 210 and synthetic traffic data 220 together for communication across a common communication channel. In doing so, the data blending engine 112 may generate a blended data stream that comprises management data 210 and synthetic traffic data 220. In the example shown in FIG. 2, the data blending engine 112 generates the blended data stream 230, which may include both management data 210 and synthetic traffic data 220. The data blending engine 112 may then communicate the blended data stream 230 to the DUT 122. As used herein, communication of the blended data stream 230 may refer to actual transmission of the blended data stream 230 through a physical communication link or to any operation that supports the transmission of the blended data stream 230 across the physical communication link. As such, the data blending engine 112 may communicate the blended data stream 230 by itself transmitting packets of the blended data stream 230 across the physical communication link, by passing the blended data stream 230 to an interface of the computing system 102 (e.g., software interface or network interface) for a next step in the communication process, or by performing any other suitable operation in support of transmission of the blended data stream 230 to a verification system.

The blended data stream 230 may support both testing and configuration of a DUT 122 through a single communication channel (e.g., single data port or communication line). The synthetic traffic data 220 of the blended data stream 230 may allow for testing of the operation of the DUT 122 (e.g., in parsing, routing, or otherwise processing communication traffic of the synthetic traffic data 220) and for configuration of the DUT 122 through the management data 210. Thus, the verification platform 120 may verify operation of devices by simulating or emulating operation of DUTs represented by the verification platform 120. The verification platform 120 may support verifications through the DUT 122 in accordance with DUT configurations specified through the management data 210 and the DUT operation testing provided through the synthetic traffic data 220.

By blending management data 210 together with a traffic data stream, the data blending engine 112 may support real-time configuration of the DUT 122, e.g., during a live testing session. Instead of cumbersome access through third-party protocols or direct altering of DUT registers via direct physical access to the verification platform 120, the data blending engine 112 may provide an efficient, flexible, and elegant mechanism by which configuration of DUTs according to management data 210 can be performed concurrently or otherwise together with DUT testing processes. Thus, the data blending engine 112 may support real-time or reactive testing techniques by blending management data 210 to alter a configuration of the DUT 122 during testing (e.g., during transmission of the synthetic traffic data 220) and analyzing behavior and response of DUT 122 after the altered configuration. In some examples, the synthetic traffic data 220 may be adapted to test specific operations of the DUT 122 for the specific or real-time changes to DUT configuration through blended management data. The data blending technology of the present disclosure may support such adaptive and dynamic configuration and testing of DUTs that conventional techniques are incapable of.

To support real-time or dynamic DUT configuration changes, the data blending engine 112 may generate the blended data stream 230 in a progressive manner. To explain further, generation and communication of the blended data stream 230 may be performed in sequences (e.g., as sequential data streams, such as a packet streams). Doing so may allow the data blending engine 112 to transmit synthetic traffic data 220 continuously and interleave management data 210 into a traffic data stream at specified times. In such examples, the data blending engine 112 need not generate the entire blended data stream 230 prior to transmission, but may instead progressively blend and construct the blended data stream 230 as interleaved data comprising synthetic traffic data 220 and management data 210. This means that the data blending engine 112 may support features to dynamically generate and blend management data 210 even when transmission of synthetic traffic data 220 has already started.

As an illustrative example, the data construction engine 110 may construct management data 210 after a first portion of the synthetic traffic data 220 has already been communicated to the DUT 122 of a verification platform 120. Such a scenario may occur responsive to a user selection to test or alter a given configuration of the DUT 122 in real-time or in mid-execution of a testbench. The data blending engine 112 may blend the constructed management data 210 with another portion of the synthetic traffic data 220 different from the first portion of the synthetic traffic data 220 already communicated to the verification platform 120. As synthetic traffic data 220 may be locally generated through scripting processes, the generation and transmission of synthetic traffic data 220 may occur in parallel with construction of management data 210, and the data blending engine 112 may blend constructed management data 210 with accessed synthetic traffic data 220. The blended data stream 230 may thus take the form of a packet stream transmitted across a communication link that comprises both management data 210 and synthetic traffic data 220 for the DUT 122.

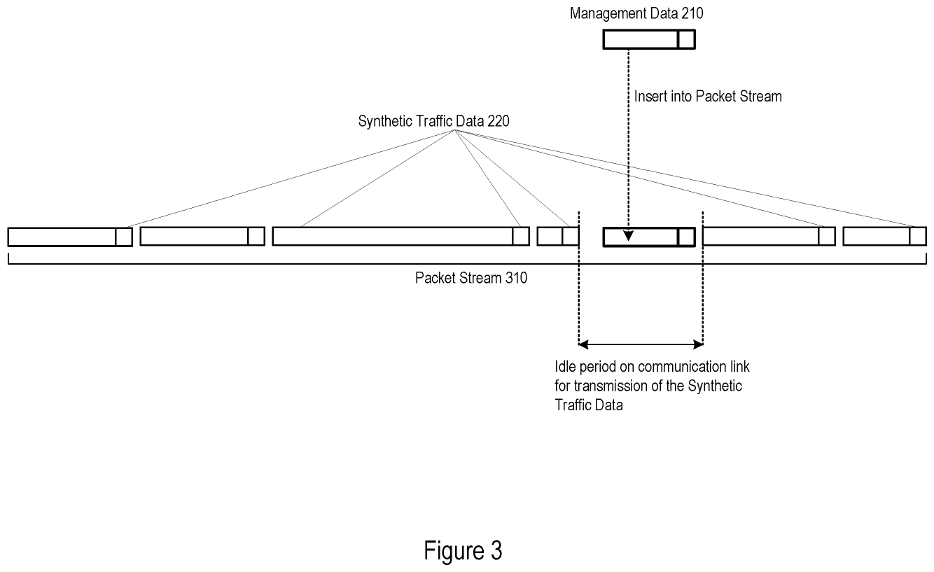

In some verification scenarios, the synthetic traffic data 220 comprises a significantly larger amount of data to communicate than the management data 210. For example, a blended data stream may comprise 99.99% synthetic traffic data 220 and 00.01% management data 210 to communicate across a common communication channel. Thus, a significant majority of communication time and resources of a computing system 102 may be dedicated to transmitting the synthetic traffic data 220 to the verification platform 120. The data blending engine 110 may blend the management data 210 with the synthetic traffic data 220 so as to not perturb a timing of transmitting the synthetic traffic data 220 to the DUT 122, for example leveraging idle periods in transmission of the synthetic traffic data 220. Example features of such techniques are described in greater detail next with reference to FIG. 3.

FIG. 3 shows an example blending of management data into a packet stream that includes synthetic traffic data. In the example of FIG. 3, the data blending engine 112 may generate a blended data stream 230 as a stream of packets, shown in FIG. 3 as the packet stream 310. The packet stream 310 may comprise packets of both management data 210 and synthetic traffic data 220, and thus the blending and communication of the blended data stream 230 by the data blending engine 112 may be effectuated through packet generation and transmission (and operations in support thereof).

To illustrate further, the synthetic traffic data 220 may comprise a large amount of data relative to the management data 210. Moreover, the synthetic traffic data 220 may include timing requirements for communication, e.g., according to Ethernet or other communication protocol timings. Thus, transmission of the packet data for the synthetic traffic data 220 may require specific line timing across a communication channel (e.g., Ethernet line). The data blending engine 112 may support blending of the management data 210 with the packet timings for the synthetic traffic data 220, and do so without perturbing to the communication timing requirements (e.g., without causing a change to the packet timing) for the synthetic traffic data 220.

In doing so, the data blending engine 112 may leverage idle periods for communication of the synthetic traffic data 220. For example, the data blending engine 112 may identify an idle period on the physical communication link or any other suitable idle period in which packet transmission of the synthetic traffic data 220 is not scheduled to occur. The data blending engine 110 may determine idle periods in any suitable manner, for example from scheduling queues for data transmission. Timing of packet transmissions may be specified via packet data (e.g., header data), which the data blending engine 112 may parse to determine suitable idle times. During such idle periods on a communication link, the data blending engine 112 may insert management data 210 for communication to verification platform 120 to configure the DUT 122. For example, the data blending engine 112 may generate a packet that comprises management data 210 and schedule the generated management data packet for communication across the physical communication line during the idle period of transmitting the synthetic traffic data 220.

Thus, in the example of FIG. 3, the blended data stream 230 comprises a packet stream 310, which may be transmitted by the computing system 102 to the verification platform 120 across a physical communication link. The data blending engine 112 may blend the management data 210 and the synthetic traffic data 220 into the blended data stream 230 by inserting the management data 210 into the packet stream 310 during idle periods in transmission of the synthetic traffic data 220. Communication of such a blended data stream 230 by the data blending engine 112 may take the form of packet scheduling of management data packets and synthetic traffic data packets or any other suitable operation in support of transmission of packets of the packet stream 310 that forms the blended data stream 230.

Idle period transmission of management data packets is but one example of how the data blending engine 112 may blend management data 210 with synthetic traffic data 220. Any suitable blending technique is contemplated herein and implementable by the data blending engine 112. As another example, the data blending engine 112 may apply a priority-based blending scheme in which packet priority is assigned to control scheduling of packet transmissions. The data blending engine 112 may assign or otherwise identify priorities for management data 210 and synthetic traffic data 220 (which may include various priorities even among different packets or data units of the management data 210 and/or synthetic traffic data 220). Then, the data blending engine 110 may communicate a blended data stream by scheduling packet transmission based on the specified priorities for packets of the management data 210 and synthetic traffic data 220.

Many data blending features have been described herein through illustrative examples presented through various figures, and the data construction engine 110 and data blending engine 112 may implement any combination of the data blending features described herein. As another example feature, the data blending engine 112 may support routing of communications from the DUT 122, e.g., responsive to transmission of a blended data stream 230. In such examples, the data blending engine 112 may provide routing capabilities, e.g., by routing response data for the synthetic traffic data 220 (e.g., egress data) to a traffic analyzer or other verification component of a computing system 102. For response data provided by the DUT 122 for the management data 210 (e.g., stateful response data), the data blending engine 112 may route such response data to the data construction engine 110, e.g., to a corresponding virtual network interface to handle stateful response data accordingly.

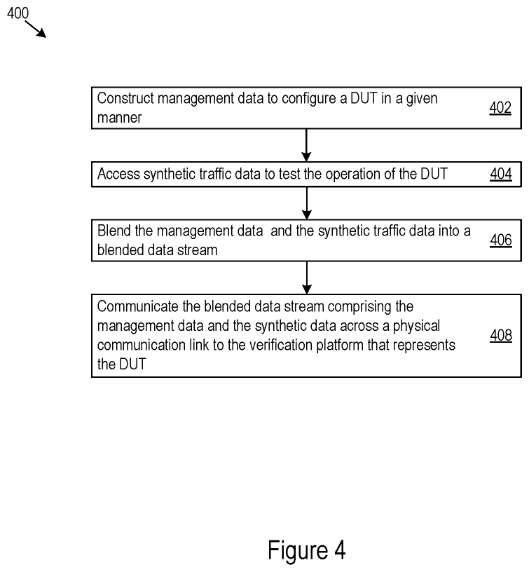

FIG. 4 shows an example of logic 400 that a system may implement to support data blending of management data and synthetic traffic data for verification of DUTs. For example, the computing system 102 may implement the logic 400 as hardware, executable instructions stored on a machine-readable medium, or as a combination of both. The computing system 102 may implement the logic 400 via the data construction engine 110 and data blending engine 112, through which the computing system 102 may perform or execute the logic 400 as a method to support data blending of management data and synthetic traffic data for verification of DUTs. The following description of the logic 400 is provided using the data construction engine 110 and data blending engine 112 as examples. However, various other implementation options by systems are possible.

In implementing the logic 400, the data construction engine 110 may construct management data to configure a DUT in a given manner (402). The DUT may take the form of a network device or network communication system, the DUT may be represented by a verification system, and the management data may take any form of data by which the DUT (and thus the network device) can be configured to operate in a particular state, according to a protocol, or in any of the ways described herein. In implementing the logic 400, the data blending engine 112 may access synthetic traffic data to test the operation of the DUT (404), for example synthetic traffic data locally generated on the computing system 102.

In implementing the logic 400, the data blending engine 112 may also blend the management data and the synthetic traffic data into a blended data stream (406) and communicate the blended data stream comprising the management data and the synthetic data across a physical communication link to the verification platform that represents the DUT (408). As used herein, communication of the blended data stream may refer to actual transmission of the blended data stream through the physical communication link or any operation that supports the transmission of the blended data stream across the physical communication link. As such, the data blending engine 112 may communicate the blended data stream by itself transmitting packets across the physical communication link, by passing the blended data stream to an interface of the computing system 102 (e.g., software interface or network interface) for a next step in the communication process, or any other suitable operation in support of transmission of the blended data stream.

The logic 400 shown in FIG. 4 provides an illustrative example by which a computing system 102 may support, implement, or provide capabilities for data blending of management data and synthetic traffic data. Additional or alternative steps in the logic 400 are contemplated herein, including according to any of the data blending technology described herein with regards to the data construction engine 110, data blending engine 112, or combinations of both.

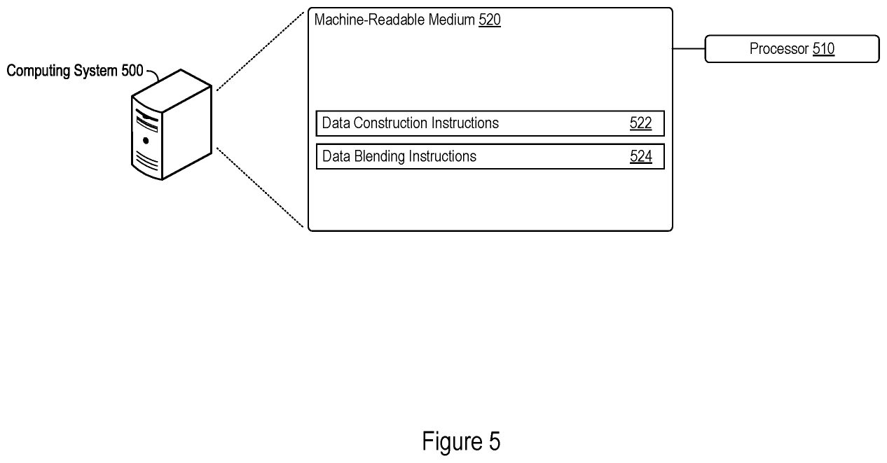

FIG. 5 shows an example of a computing system 500 that supports data blending of management data and synthetic traffic data for verification of DUTs. The computing system 500 may include a processor 510, which may take the form of a single or multiple processors. The processor(s) 510 may include a central processing unit (CPU), microprocessor, or any hardware device suitable for executing instructions stored on a machine-readable medium. The computing system 500 may include a machine-readable medium 520. The machine-readable medium 520 may take the form of any non-transitory electronic, magnetic, optical, or other physical storage device that stores executable instructions, such as the data construction instructions 522 and the data blending instructions 524 shown in FIG. 5. As such, the machine-readable medium 520 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 500 may execute instructions stored on the machine-readable medium 520 through the processor 510. Executing the instructions (e.g., the data construction instructions 522 and/or the data blending instructions 524) may cause the computing system 500 to perform any of the data blending features described herein, including according to any of the features of the data construction engine 110, data blending engine 112, or combinations of both.

For example, execution of the data construction instructions 522 by the processor 510 may cause the computing system 500 to construct management data to configure a DUT in a given manner. The DUT may take the form of a network device, the DUT may be represented by a verification system, and the management data may take any form by which the DUT can be configured to operate in a particular state, according to a protocol, or in any of the ways described herein. Execution of the data blending instructions 524 by the processor 510 may cause the computing system 500 to access synthetic traffic data to test the operation of the DUT, for example synthetic traffic data locally generated on the computing system 500.

Execution of the data blending instructions 524 by the processor 510 may also cause the computing system 500 to blend the management data and the synthetic traffic data into a blended data stream and communicate the blended data stream comprising the management data and the synthetic data across a physical communication link to the verification platform that represents the DUT. As described herein, communication of the blended data stream may refer to actual transmission of the blended data stream through the physical communication link or any operation that supports the transmission of the blended data stream across the physical communication link.

Any additional or alternative data blending features as described herein may be implemented via the data construction instructions 522, data blending instructions 524, or a combination of both.

The systems, methods, devices, and logic described above, including the data construction engine 110 and data blending engine 112, may be implemented in many different ways in many different combinations of hardware, logic, circuitry, and executable instructions stored on a machine-readable medium. For example, the data construction engine 110, data blending engine 112, or combinations thereof, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the data construction engine 110, data blending engine 112, or combinations thereof.

The processing capability of the systems, devices, and engines described herein, including the data construction engine 110 and data blending engine 112, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples have been described above, many more implementations are possible.

1. A method comprising:
by a computing system communicatively linked to a verification platform that represents a design-under-test (DUT) to verify operation of the DUT:
constructing management data to configure the DUT in a given manner;
accessing synthetic traffic data to test the operation of the DUT;
blending the management data and the synthetic traffic data into a blended data stream; and
communicating the blended data stream comprising the management data and the synthetic data across a physical communication link to the verification platform that represents the DUT.

2. The method of claim 1, wherein the blended data stream comprises a packet stream transmitted by the computing system to the verification platform across the physical communication link, and wherein blending the management data and the synthetic traffic data into the blended data stream comprises inserting the management data into the packet stream during idle periods in transmission of the synthetic traffic data.

3. The method of claim 1, comprising constructing the management data according to a user input to configure the DUT for verification in the given manner.

4. The method of claim 1, comprising constructing the management data after a first portion of the synthetic traffic data has already been communicated to the verification platform, and
comprising blending the management data with another portion of the synthetic traffic data different from the first portion of the synthetic traffic data already communicated to the verification platform.

5. The method of claim 1, wherein the management data configures a state of the DUT, a communication protocol used by the DUT, or a combination of both.

6. The method of claim 1, wherein the management data comprises data of a management plane for the DUT, and
wherein the synthetic traffic data comprises data of a data plane of the DUT, data of a control plane of the DUT, or a combination of both.

7. The method of claim 1, further comprising verifying, by the verification platform, the operation of the DUT by simulating or emulating the operation of the DUT represented by the verification platform.

8. A system comprising:
a verification platform configured to represent a design-under-test (DUT) to verify operation of the DUT; and
a computing system comprising:
a processor; and
a non-transitory machine-readable medium comprising instructions that, when executed by the processor, cause the computing system to:
construct management data to configure the DUT in a given manner;
access synthetic traffic data to test the operation of the DUT;
blend the management data and the synthetic traffic data into a blended data stream; and
communicate the blended data stream comprising the management data and the synthetic data across a physical communication link to the verification platform that represents the DUT.

9. The system of claim 8, wherein the blended data stream comprises a packet stream transmitted by the computing system to the verification platform across the physical communication link, and
wherein the instructions, when executed, cause the computing system to blend the management data and the synthetic traffic data into the blended data stream by inserting the management data into the packet stream during idle periods in transmission of the synthetic traffic data.

10. The system of claim 8, wherein the instructions, when executed, cause the computing system to construct the management data according to a user input to configure the DUT for verification in the given manner.

11. The system of claim 8, wherein the instructions, when executed, cause the computing system to construct the management data after a first portion of the synthetic traffic data has already been communicated to the verification platform, and
wherein the instructions, when executed, cause the computing system to blend the management data with another portion of the synthetic traffic data different from the first portion of the synthetic traffic data already communicated to the verification platform.

12. The system of claim 8, wherein the management data configures a state of the DUT, a communication protocol used by the DUT, or a combination of both.

13. The system of claim 8, wherein the management data comprises data of a management plane for the DUT, and
wherein the synthetic traffic data comprises data of a data plane of the DUT, data of a control plane of the DUT, or a combination of both.

14. The system of claim 8, wherein the verification platform is further configured to verify the operation of the DUT by simulating or emulating the operation of the DUT represented by the verification platform.

15. A non-transitory computer-readable medium comprising instructions that, when executed by a processor, cause a computing system to:
construct management data to configure a design-under-test (DUT) in a given manner, wherein the DUT is represented by a verification platform that is communicatively linked to the computing system;
access synthetic traffic data to test the operation of the DUT;
blend the management data and the synthetic traffic data into a blended data stream; and
communicate the blended data stream comprising the management data and the synthetic data across a physical communication link to the verification platform that represents the DUT.

16. The non-transitory computer-readable medium of claim 15, wherein the blended data stream comprises a packet stream transmitted by the computing system to the verification platform across the physical communication link, and
wherein the instructions, when executed, cause the computing system to blend the management data and the synthetic traffic data into the blended data stream by inserting the management data into the packet stream during idle periods in transmission of the synthetic traffic data.

17. The non-transitory computer-readable medium of claim 15, wherein the instructions, when executed, cause the computing system to construct the management data according to a user input to configure the DUT for verification in the given manner.

18. The non-transitory computer-readable medium of claim 15, wherein the instructions, when executed, cause the computing system to:
construct the management data after a first portion of the synthetic traffic data has already been communicated to the verification platform; and
blend the management data with another portion of the synthetic traffic data different from the first portion of the synthetic traffic data already communicated to the verification platform.

19. The non-transitory computer-readable medium of claim 15, wherein the management data configures a state of the DUT, a communication protocol used by the DUT, or a combination of both.

20. The non-transitory computer-readable medium of claim 15, wherein the management data comprises data of a management plane for the DUT, and
wherein the synthetic traffic data comprises data of a data plane of the DUT, data of a control plane of the DUT, or a combination of both.
